(19) United States
(12) Patent Application Publication
(10) Pub. No.: US 2010/0167429 A1
(43) Pub. Date: Jul. 1, 2010

(54) METHOD OF MANUFACTURING SEMICONDUCTOR DEVICE

(76) Inventor: Seong-Hun Jeong, Nowon-gu (KR)

Correspondence Address: SHERR & VAUGHN, PLLC, 620 HERNDON PARKWAY, SUITE 320, HERNDON, VA, 20170, US

(21) Appl. No.: 12/643,026

(22) Filed: Dec. 21, 2009

(30) Foreign Application Priority Data
Dec. 31, 2008 (KR) 10-2008-0137689

(51) Int. Cl. H01L 21/66; H01L 21/321; H01L 21/768

(52) U.S. Cl. 438/14; 438/692; 438/668; 257/E21.53; 257/E21.304; 257/E21.585

(57) ABSTRACT

A method of manufacturing a semiconductor device estimates the level of erosion generated in CMP of a plug by using a monitoring pattern that defines uniformly a hole array size (split a) and the length (split b) of the space between arrays.

### CROSS-REFERENCE TO RELATED APPLICATION

The present application claims priority under 35 U.S.C. §119 to Korean Patent Application No. 10-2008-0137689 (filed Dec. 31, 2008), which is hereby incorporated by reference in its entirety.

### BACKGROUND

Semiconductor devices may have a metal layer and a plug that can transmit electrons to activate a transistor. The plug in such a configuration may be formed by performing a planarization process such as CMP on a tungsten (W) material that has been gap-filled or by using a dual damascene method. When the plug is formed by CMP after gap-filling W, dishing/erosion is caused by the CMP process. Dishing causes non-contact between the plug and the metal layer and erosion causes a defect of plug that is not opened. The dishing can be reduced by performing CMP on W in two steps or using slurry of a low selection ratio, whereas it is difficult to estimate the level of the erosion.

### SUMMARY

Embodiments relate to a method of manufacturing a semiconductor device that finds an amount of erosion generated in CMP of a metal such as tungsten, etc. while increasing stability of the processes by providing a pattern that allows for monitoring erosion after CMP of tungsten.

In accordance with embodiments, a method of manufacturing a semiconductor device may include at least one of the following: estimating the level of erosion generated in CMP of a plug by using a monitoring pattern that defines uniformly a hole array size (split a) and the length (split b) of the space between arrays.

In accordance with embodiments, a method of manufacturing a semiconductor device may include at least one of the following: forming a hole in a layer; filling the hole with a metal material; forming a plug by conducting a chemical mechanical polishing process on the metal material; and then estimating a level of erosion generated during the chemical mechanical polishing process.

In accordance with embodiments, a method of manufacturing a semiconductor device may include at least one of the following: forming a plug by conducting a chemical mechanical polishing process on a material comprising tungsten; estimating a level of erosion generated during the chemical mechanical polishing process by a monitoring process that uses a monitoring pattern that uniformly defines a hole array size and a length of the space between arrays.

### DRAWINGS

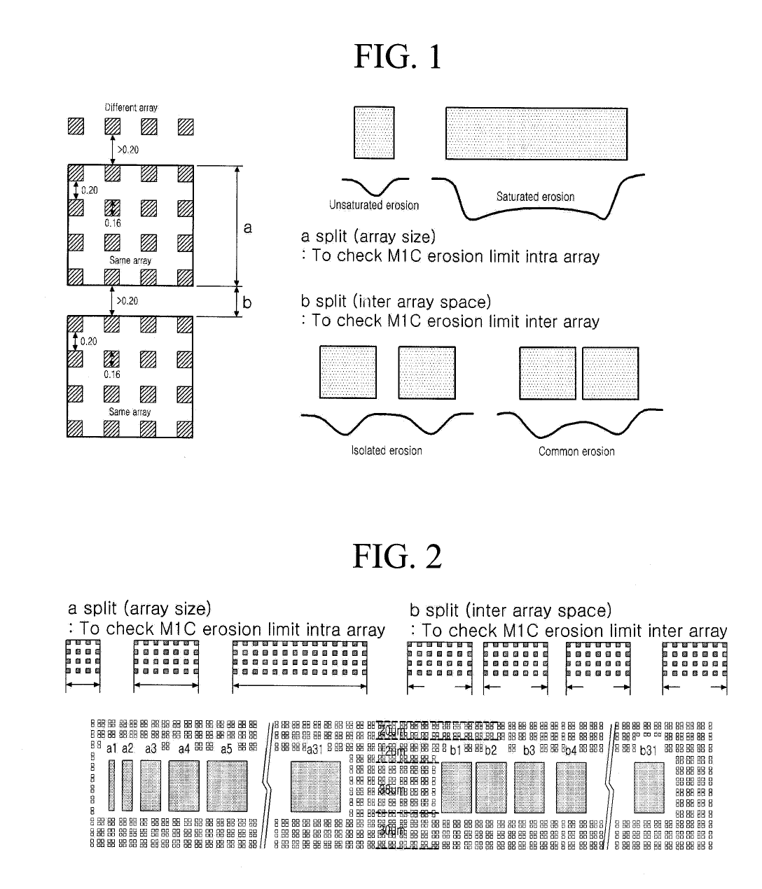

Example FIGS. 1 to 4 illustrate a method of manufacturing a semiconductor device, in accordance with embodiments.

### DESCRIPTION

Hereinafter, a method of manufacturing a semiconductor device in accordance with embodiments will be described with reference to the accompanying drawings.

In the description of embodiments, it will be understood that when a layer (or film) is referred to as being “on” another layer or substrate, it can be directly on another layer or substrate, or intervening layers may also be present. Further, it will be understood that when a layer is referred to as being “under” another layer, it can be directly under another layer, and one or more intervening layers may also be present. In addition, it will also be understood that when a layer is referred to as being “between” two layers, it can be the only layer between the two layers, or one or more intervening layers may also be present.

A method of manufacturing a semiconductor device in accordance with embodiments estimates the level of erosion generated in CMP of a plug by using a monitoring pattern that defines uniformly a hole array size (split a) and the length (split b) of the space between arrays. In accordance with embodiments, influence of the hole array size increases in accordance with the hole array size. Moreover, in accordance with embodiments, influence of the hole array size increases in accordance with the hole array size while the erosion amount is monitored whether to be saturated in a predetermined size. Even still, in accordance with embodiments, erosion is generated in inverse proportion to the space between arrays and the length of the space that is influenced between the arrays is monitored.

In accordance with embodiments, tungsten (W) is illustrated as the material composition of the plug, but it is not limited thereto. Further, in accordance with embodiments, CMP is exemplified as a method of planarization for forming the plug, but it is not limited thereto.

In accordance with embodiments, in order to form a plug, a hole pattern is formed, a barrier metal is deposited, and a hole is filled with a metal such as tungsten (W) by a method such as CVD. Thereafter, CMP is performed to remove remaining bulk tungsten (W). There are dishing and erosion as side effects of CMP of tungsten.

In accordance with embodiments, a pattern is used for erosion monitoring. The erosion is generated on an oxide layer where the plug exists, the degree of influencing the generation is as follows. The most influential factor is first local density of a hole forming the plug, the second is the area of a plug area, and the third is a space between the plug areas. The monitoring pattern is proposed in consideration of the three factors.

The first factor is a factor that is difficult to adjust under a design rule. It is generally regulated that the hole size is 0.16 μm and the inter-hole distance is 0.2 μm at 130 nm tech.

As illustrated in example FIG. 2, a monitoring pattern is formed by uniformly regulating the hole array size (split a) and the length (split b) of a space between arrays, as illustrated in example FIG. 1.

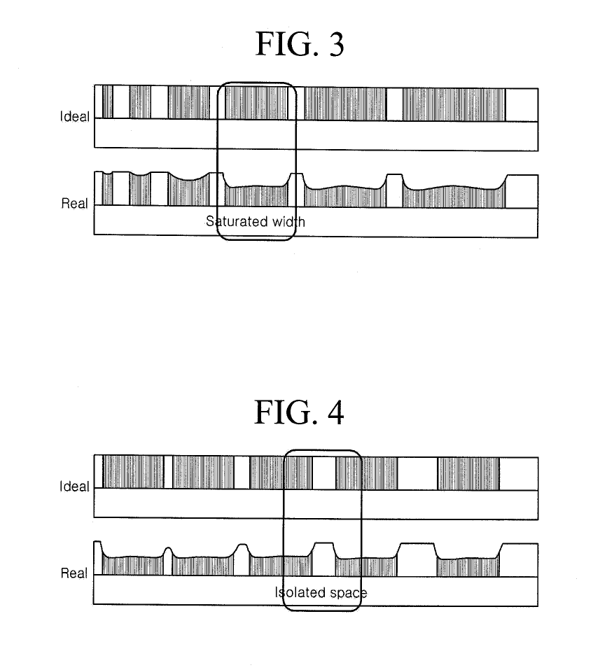

As illustrated in example FIG. 3, it can be seen that influence of the hole array size increases in accordance with the hole array size. Also, the erosion amount can be monitored whether to be saturated at any predetermined size.

As illustrated in example FIG. 4, there is a length of space between arrays. Erosion is generated in inverse proportion to the space between arrays. In accordance with embodiments, the length of the space that is influenced between the arrays is monitored. It is possible to estimate the level of erosion that is generated in W-CMP using the monitoring pattern, and prevent defects in the following processes.

According to a method of manufacturing a semiconductor device of the embodiment, it is possible to find the erosion amount that is generated in CMP of tungsten etc. and increase stability of the following processes, by providing a pattern that allows for monitoring erosion after CMP of tungsten etc., by estimating erosion according to the plug array size and the length of the space.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device comprising:
estimating a level of erosion generated in a chemical mechanical polishing of a plug using a monitoring pattern that uniformly defines a hole array size and a length of the space between arrays.

2. The method of claim 1, wherein influence of the hole array size increases in accordance with the hole array size.

3. The method of claim 2, wherein the level of erosion is monitored whether to be saturated in a predetermined size.

4. The method of claim 1, wherein erosion is generated in inverse proportion to the space between arrays.

5. The method of claim 4, wherein the length of the space between arrays that is influenced therebetween is monitored.

6. The method of claim 4, wherein influence of the hole array size increases in accordance with the hole array size.

7. The method of claim 6, wherein the level of erosion is monitored whether to be saturated in a predetermined size.

8. The method of claim 2, wherein erosion is generated in inverse proportion to the space between arrays.

9. The method of claim 8, wherein the length of the space that is influenced between the arrays is monitored.

10. A method of manufacturing a semiconductor device comprising:
forming a hole in a layer;
filling the hole with a metal material;
forming a plug by conducting a chemical mechanical polishing process on the metal material; and then estimating a level of erosion generated during the chemical mechanical polishing process.

11. The method of claim 10, wherein estimating the level of erosion comprises performing a monitoring using a monitoring pattern that uniformly defines a hole array size and a length of the space between arrays.

12. The method of claim 11, wherein influence of the hole array size increases in accordance with the hole array size.

13. The method of claim 12, wherein the level of erosion is monitored whether to be saturated in a predetermined size.

14. The method of claim 10, wherein the metal material comprises tungsten.

15. The method of claim 11, wherein erosion is generated in inverse proportion to the space between arrays.

16. The method of claim 15, wherein performing the monitoring comprises monitoring the length of the space between arrays that is influenced therebetween.

17. A method of manufacturing a semiconductor device comprising:
forming a plug by conducting a chemical mechanical polishing process on a material comprising tungsten;
estimating a level of erosion generated during the chemical mechanical polishing process by a monitoring process that uses a monitoring pattern that uniformly defines a hole array size and a length of the space between arrays.

18. The method of claim 10, wherein influence of the hole array size increases in accordance with the hole array size.

19. The method of claim 18, wherein the level of erosion is monitored whether to be saturated in a predetermined size.

20. The method of claim 10, wherein erosion is generated in inverse proportion to the space between arrays.
